(19) United States
(12) Patent Application Publication
(10) Pub. No.: US 2006/0202614 A1
(43) Pub. Date: Sep. 14, 2006

(54) Organic electroluminescent devices and display device employing the same

(75) Inventor: Shi-Hao Li, Banciao City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: AU Optronics Corp.

(21) Appl. No.: 11/202,847

(22) Filed: Aug. 12, 2005

(30) Foreign Application Priority Data
Mar. 9, 2005 (TW) 94107101

(51) Int. Cl. H01L 51/50; H05B 33/12

(52) U.S. Cl. 313/506; 428/690; 428/917; 313/504

(57) ABSTRACT

An organic electroluminescent device and a display device including the same. The organic electroluminescent device can be a top-emission or dual emission organic electroluminescent device and comprises at least one substrate, an anode electrode on the substrate, an electroluminescent material layer on the anode, a buffer layer on the electroluminescent material layer, and a transparent cathode electrode on the buffer layer, wherein the buffer layer comprises n-type semiconductor material.

### BACKGROUND

The present invention relates to an organic electroluminescent device and, more particularly, to a top-emission or dual emission organic electroluminescent device.

Recently, with the development and wide application of electronic products, such as mobile phones, PDA, and notebook computers, there has been increasing demand for flat display elements which consume less electric power and occupy less space. Among flat panel displays, organic electroluminescent devices are self-emitting, and highly luminous, with wider viewing angle, faster response, and a simple fabrication process, making them the industry display of choice.

An organic light-emitting diode (OLED) is an increasingly popular light-emitting diode that uses an organic electroluminescent layer. According to the direction from which the light is obtained, organic electroluminescent devices are classified as bottom-emission, top-emission, or dual emission organic electroluminescent devices.

Top-emission and dual emission organic electroluminescent devices comprise a transparent cathode and an anode and organic electroluminescent layers, wherein light emitted by the organic electroluminescent devices passes through the transparent cathode outward. In general, methods for fabricating the transparent cathode comprise forming a thin metal layer, such as Mg, Ag, or Al, by thermal evaporation or forming a transparent conductive layer, such as ITO or IZO, by sputtering. Since the thin metal layers formed by thermal evaporation have inferior adhesion to electroluminescent materials and lower transparency, ITO or IZO electrode layers formed by sputtering are widely used due to higher transparency.

In sputtering of a transparent conductive layer, the top surface of the underlying electroluminescent layer oxidizes, deteriorates, and roughens by ion bombardment during the sputter deposition. Thus, the energy barriers of the interfaces between the transparent cathode and the electroluminescent layers increase, and the carrier movement between layers is less likely to occur, resulting in a higher operating voltage and shorter lifetime.

Accordingly, an organic electroluminescent device having an organic material or polymer layer, formed on the underlying electroluminescent layers as buffer layer has been developed to prevent damage to the underlying electroluminescent layers and solve problems of conventional technology. For example, U.S. Pat. No. 6,402,579 discloses a MEH-PPV layer and U.S. Pat. No. 6,420,031 discloses a CuPc layer serving as buffer layer. The aforementioned method avoids the underlying electroluminescent layer deterioration. However, roughness of the interface between the buffer layer and the transparent cathode is still increased.

In general, after sputtering, the transparent cathode is subjected to an annealing process to reduce sheet resistance to 30 Ω/sq. Since the electroluminescent layers are formed before the transparent cathode in the fabrication process of top-emission and dual emission organic electroluminescent devices, the annealing process is inhibitive, to prevent damage to the electroluminescent layers. Thus, the transparent cathode has a sheet resistance of 100 Ω/sq, resulting in a higher operating voltage and reduced luminance efficiency.

Therefore, it is necessary to develop organic electroluminescent devices with novel structure and low operating voltage in order to accommodate in to practical use.

### SUMMARY

Embodiments of the invention provide an organic electroluminescent device, comprising a substrate, a first electrode such as an anode, an electroluminescent layer, a buffer layer, and a second electrode such as a transparent cathode, wherein the buffer layer comprises an n-type semiconductor material. The n-type semiconductor material with hole-transport properties prevents damage to the underlying electroluminescent layers. Furthermore, due to the sufficient rigidity of the n-type semiconductor material, the roughness of the interface between the n-type semiconductor buffer layer and the transparent cathode is minimized enough to avoid large leakage current or point discharge causing pixel defects. The organic electroluminescent devices can be top-emission or dual emission organic electroluminescent device.

According to some embodiment of the invention, the transparent cathode comprises a transparent electrode layer, a metal layer, and a protection layer in sequence. The provided transparent cathode has low sheet resistance, reducing the bias voltage of common drain electrode (transparent cathode) of a display panel.

Further provided is a display device, such as an organic electroluminescent display device, comprising the disclosed organic electroluminescent device and a power source element, wherein the power source element electrically couples to the organic electroluminescent device.

A detailed description is given in the following with reference to the accompanying drawing.

### BRIEF DESCRIPTION OF THE DRAWINGS

The invention can be more fully understood by reading the subsequent detailed description in conjunction with the examples and references made to the accompanying drawings, wherein:

FIG. 1 is a cross section of an organic electroluminescent device according to an embodiment of the invention.

FIG. 2 is a cross section of an organic electroluminescent device according to embodiments of the invention.

FIG. 3 is a cross section of an organic electroluminescent device according to embodiments of the invention.

FIG. 4 is a graph plotting thickness of the metal layer 20b shown in FIG. 3 against sheet resistance of the cathode electrode 20 shown in FIG. 3.

FIG. 5 is a graph plotting thickness of the metal layer 20b shown in FIG. 3 against transparency of the cathode electrode 20 shown in FIG. 3.

FIG. 6 is a cross section of an organic electroluminescent device according to Working Example 1.

FIG. 7 is a cross section of an organic electroluminescent device according to Working Example 2.

FIG. 8 is a cross section of an organic electroluminescent device according to Comparative Example 1.

FIG. 9 is a graph plotting operating voltage against current density of organic electroluminescent devices as disclosed in Working Example 1, Working Example 2, and Comparative Example 1.

FIG. 10 is a graph plotting operating voltage against brightness of organic electroluminescent devices as disclosed in Working Example 1, Working Example 2, and Comparative Example 1.

FIG. 11 is a graph plotting operating voltage against CIE chromaticity coordinates (X axis) of organic electroluminescent devices as disclosed in Working Example 1, Working Example 2, and Comparative Example 1.

FIG. 12 is a graph plotting operating voltage against CIE chromaticity coordinates (Y axis) of organic electroluminescent devices as disclosed in Working Example 1, Working Example 2, and Comparative Example 1.

FIG. 13 is a graph plotting operating voltage against luminant efficiency of organic electroluminescent devices as disclosed in Working Example 1, Working Example 2, and Comparative Example 1.

### DETAILED DESCRIPTION

One feature of the invention is use of a combination of an electroluminescent layer, a transparent electrode, and a n-type semiconductor buffer layer formed between the two layers. Organic electroluminescent devices of embodiments comprise at least a substrate, an anode electrode on the substrate, an electroluminescent material layer on the anode, a buffer layer on the electroluminescent material layer, and a transparent cathode electrode on the buffer layer, wherein the buffer layer comprises a n-type semiconductor material.

A method of fabricating an organic electroluminescent device according to an embodiment of the invention follows.

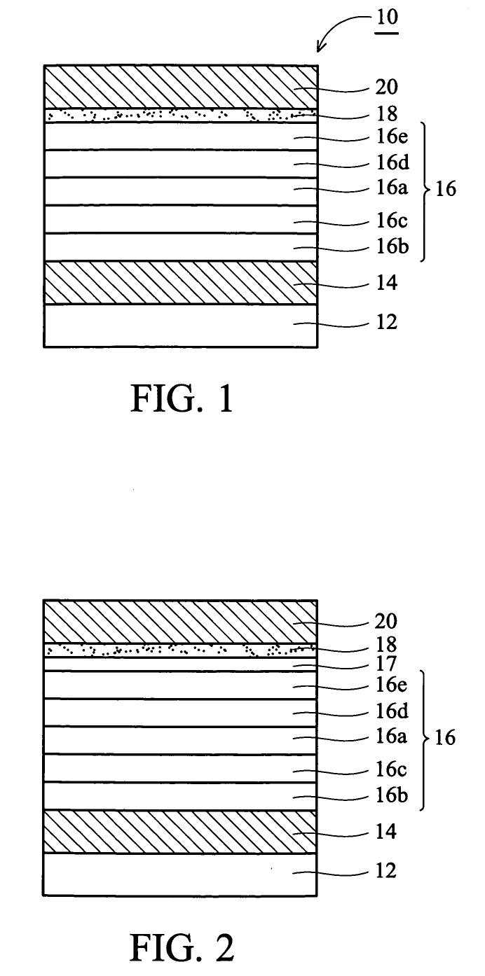

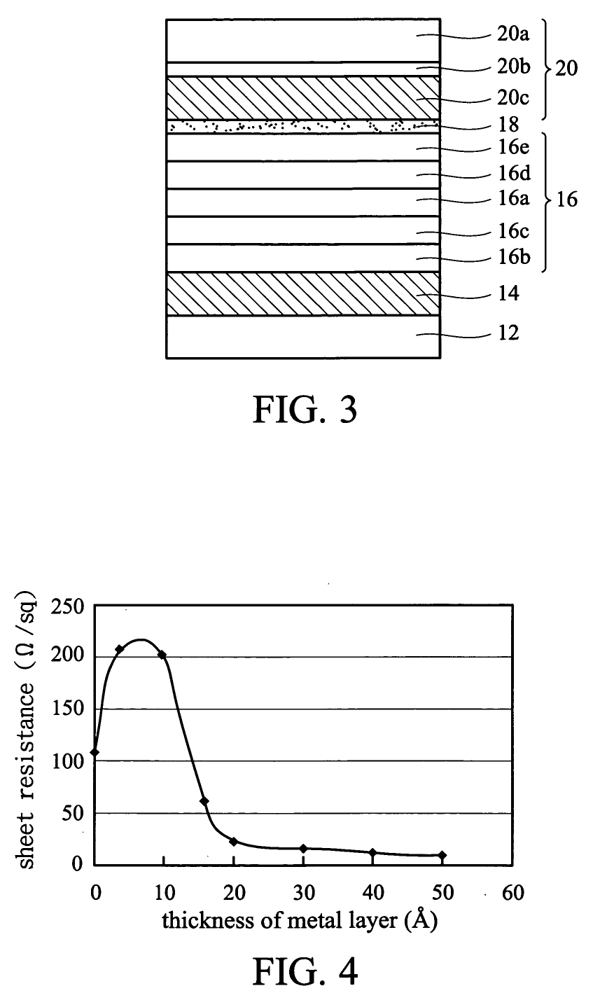

As shown in FIG. 1, a substrate 12 is provided, of an insulating material such as glass, plastic, or ceramic. Further, the substrate 12 can be a semiconductor substrate, transparent or optionally opaque, specifically a transparent substrate when the organic electroluminescent device 10 is a dual emission organic electroluminescent device, and an opaque substrate when the organic electroluminescent device 10 is a top-emission organic electroluminescent device.

A first electrode such as an anode electrode 14 is formed on the substrate 12, and can be a transparent electrode, metal electrode, or combinations thereof, comprising indium tin oxide (ITO), indium zinc oxide (IZO), aluminum zinc oxide (AZO), zinc oxide (ZnO), Li, Mg, Ca, Al, Ag, In, Au, Ni, Pt, or alloys thereof, formed by a method such as sputtering, electron beam evaporation, thermal evaporation, or chemical vapor deposition. In an embodiment of the invention, a reflective layer is formed between the substrate 12 and the anode electrode 14.

An electroluminescent layer 16 is formed on the anode electrode 14, wherein the electroluminescent layer 16 at least comprises a light emitting layer 16a, and can further comprises a hole injection layer 16b, a hole transport layer 16c, an electron transport layer 16d, and an electron injection layer 16e, as shown in FIG. 1. The electroluminescent layer 16 is organic semiconductor material such as small molecule material, polymer, or organometallic complex, and can be formed by thermal vacuum evaporation, spin coating, dip coating, roll-coating, injection-fill, embossing, stamping, physical vapor deposition, or chemical vapor deposition. The emitting layer 16a comprises a light-emitting material and an electroluminescent dopant doped into the light-emitting material and can perform energy transfer or carrier trapping under electron-hole recombination in the emitting layer. The light-emitting material can be fluorescent or phosphorescent.

A buffer layer 18 is formed on the electroluminescent layer 16, comprising an n-type semiconductor material, such as fullerene. The n-type semiconductor material has an energy gap of more than 1.0 eV. The thickness of the buffer layer is 10˜2000 Å, preferably 50˜1500 Å. Referring to FIG. 2, organic electroluminescent devices of embodiments further comprise a metal conductive layer 17 formed between the electroluminescent layer 16 and the buffer layer 18. The conductive layer, such as Al, can have a thickness of 10˜500Å.

A transparent electrode, such as a transparent cathode electrode 20, is formed on the buffer layer 18. It should be noted that transparent cathode electrode 20 is formed directly on the buffer layer 18. The transparent cathode electrode 20 can comprise ITO, IZO, AZO, ZnO, GaN(gallium nitride), GaInN (gallium indium nitride), CdS(cadmium sulfide), ZnS (zinc sulfide), CdSe (cadmium selenide), or ZnSe (zinc selenide).

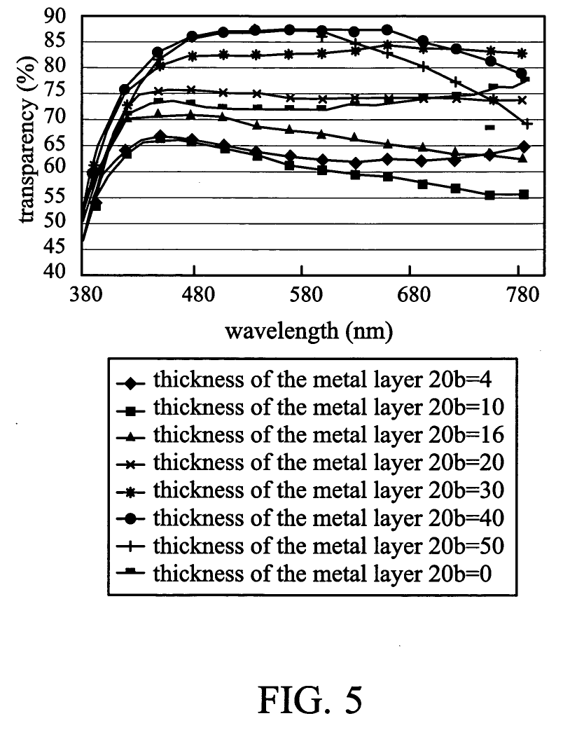

Furthermore, according to some embodiments of the invention, the transparent cathode electrode 20 can be a composite structure and comprise a transparent electrode 20a on the buffer layer 18, a metal layer on 20b the transparent layer 20a, and a protective layer 20c on the metal layer 20b. The transparent electrode 20a can comprise ITO, IZO, AZO, ZnO, GaN, GaInN, CdS, ZnS, CdSe, or ZnSe. The protective layer 20c can be transparent conductive material, conductive polymer material, or semiconductor material with wide energy gap, such as ITO, IZO, AZO, ZnO, GaN, GaInN, CdS, ZnS, CdSe, ZnSe, polypyrrole, polyaniline, or polythiophene. In order to reduce sheet resistance of the transparent cathode electrode 20, the metal layer 20b preferably has electrical conductivity exceeding 105 cm⁻¹Ω^{31 1}. For example, the metal layer 20b can be made of Ag. The relationship between thickness of the metal layer 20b and sheet resistance of the cathode electrode 20 is shown in FIG. 4, and the relationship between thickness of the metal layer 20b and transparency of the cathode electrode 20 is shown in FIG. 5. Accordingly, a metal layer 20b with a thickness of 20˜50 Å exhibits superior performance.

### WORKING EXAMPLE 1

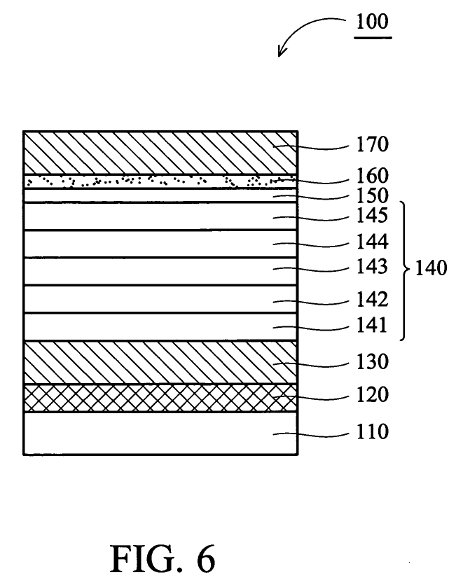

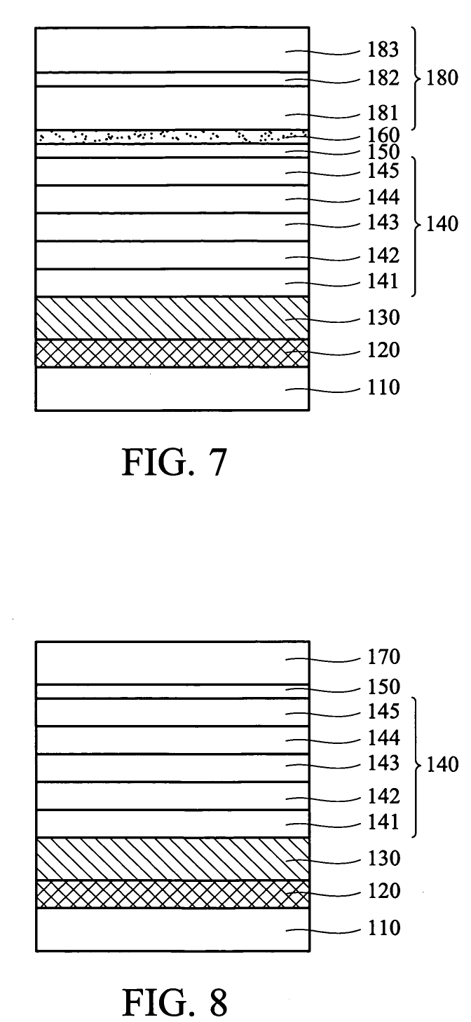

As shown in FIG. 6, the organic electroluminescent device 100 used here was a top-emission organic electroluminescent device. A reflective layer 120 was formed on a glass substrate 110, of Ti with a thickness of 500 Å. An ITO electrode 130 with a thickness of 750 Å, a hole injection layer 141, a hole transport layer 142, an emitting layer 143, an electron transport layer 144, an electron injection layer 145, a thin conductive layer 150, a buffer layer 160, and a transparent cathode electrode 170 were all formed subsequently on the reflection layer 120. The a hole injection layer 141, hole transport layer 142, emitting layer 143, electron transport layer 144, and electron injection layer 145 comprise an electroluminescent layer 140.

For purposes of clarity, materials and layers formed therefrom are described as follows.

The hole injection layer 141, at a thickness of 200 Å, consisted of CuPc (copper phthalocyanine). The hole transport mixed layer 142, at a thickness of 400 Å, consisted of NPB (N,N′-di-1-naphthyl-N,N′-diphenyl-1,1′-biphenyl-1,1′-biphenyl-4,4′-diamine). The emitting layer 143, at thickness of 300 Å, consisted of C545T (10-(2-Benzothiazolyl)-2,3,6,7-tetrahydro-1,1,7,7-tetramethyl-1H,5H,11H-(1)-benzopyropyrano(6,7-8-i,j)quinolizin-11-one) as dopant, and NPB and Alq₃(tris (8-hydroxyquinoline) aluminum) as light-emitting materials, wherein the weight ratio between NBP and Alq₃ was 1:1 and the dopant amount of C545T 1.1% by weight. The electron transport layer 144, at a thickness of 400 Å, consisted of Alq₃. The electron injection layer 145, at a thickness of 10 Å, consisted of LiF (lithium fluoride). The thin conductive layer 150, at a thickness of 20 Å, consisted of Al. The buffer layer 160, at a thickness of 50 Å, consisted of fullerene. The tansparent cathode electrode 170, at a thickness of 800 Å, consisted of IZO.

The structure of the organic electroluminescent device 100 was:

Ti 500 Å/ITO 750 Å/CuPc 200 Å/NPB 400 Å/Alq₃:NPB=1:1):C545T1.1% 300 Å/Alq₃ 400 Å/LiF 10 Å/Al 20 Å/fullerene 50 Å/IZO 800 Å

The measured results of optical properties for the oganic electroluminescent device, as described in Working Eample 1, are shown in Table 1.

TABLE 1
Optical Properties for Working Example 1

| | | | CIE | CIE | Peak |
|---|---|---|---|---|---|
| | Current | | chromaticity | chromaticity | Wave- |
| Voltage | Density | Brightness | coordinates | coordinates | length |
| (V) | (mA/cm²) | (cd/m²) | (X axis) | (Y axis) | (nm) |
| 1 | 0 | 0 | 0 | 0 | 0 |
| 2 | 0 | 0 | 0 | 0 | 0 |
| 3 | 0.04 | 0 | 0 | 0 | 0 |
| 4 | 0.51 | 24.59 | 0.252 | 0.675 | 520 |
| 5 | 2.66 | 137.4 | 0.251 | 0.675 | 520 |
| 6 | 9.96 | 516.3 | 0.251 | 0.675 | 520 |
| 7 | 31.98 | 1586 | 0.25 | 0.673 | 520 |
| 8 | 87.78 | 4277 | 0.25 | 0.672 | 520 |

### WORKING EXAMPLE 2

Working Example 2 was executed as Working Example 1 except for substitution of a composite transparent cathode electrode 180 for the transparent cathode electrode 170. The composite transparent cathode electrode 180 comprised a transparent conductive layer 181 on the buffer layer 170, a metal layer 182 on the transparent conductive layer 181, and a protective layer 183 on the metal layer 182. The transparent conductive layer 181, at a thickness of 400 Å, consisted of IZO. The metal layer 182, at a thickness of 20 Å, consisted of Ag. The protective layer 183, at a thickness of 400 Å, consisted of IZO.

The structure of the organic electroluminescent device was:

Ti 500 Å/ITO 750 Å/CuPc 200 Å/NPB 400 Å/(Alq₃:NPB=1:1):C545T1.1% 300 Å/Alq₃ 400 Å/LiF 10 Å/Al 20 Å/fullerene 50 Å/IZO 400 Å/Ag20 Å/IZO400 Å

The measured results of optical properties for the organic electroluminescent device, as described in Working Example 2, are shown in Table 2.

TABLE 2
Optical Properties for Working Example 1

| | | | CIE | CIE | Peak |
|---|---|---|---|---|---|
| | Current | | chromaticity | chromaticity | Wave- |
| Voltage | Density | Brightness | coordinates | coordinates | length |
| (V) | (mA/cm²) | (cd/m²) | (X axis) | (Y axis) | (nm) |
| 1 | 0 | 0 | 0 | 0 | 0 |
| 2 | 0 | 0 | 0 | 0 | 0 |
| 3 | 0.07 | 0 | 0 | 0 | 0 |
| 4 | 1.11 | 50.1 | 0.301 | 0.656 | 524 |
| 5 | 6.34 | 298.4 | 0.3 | 0.658 | 524 |
| 6 | 23.99 | 1124 | 0.299 | 0.658 | 524 |
| 7 | 72.05 | 3278 | 0.298 | 0.657 | 524 |
| 8 | 187.91 | 8638 | 0.298 | 0.657 | 524 |

### COMPARATIVE EXAMPLE 1

Comparative Example 1 was executed as Working Example 1 except for removal of the buffer layer 160, referring to FIG. 8. The structure of the organic electroluminescent device was:

Ti 500 Å/ITO 750 Å/CuPc 200 Å/NPB 400 Å/(Alq₃:NPB=1:1):C545T1.1% 300 Å/Alq₃ 400 Å/LiF 10 Å/Al 20 Å/IZO 800 Å

The measured results of optical properties for the oganic electroluminescent device, as described in Comparative Example 1, are shown in Table 3.

TABLE 3
Optical Properties for Working Example 1

| | | | CIE | CIE | Peak |
|---|---|---|---|---|---|
| | Current | | chromaticity | chromaticity | Wave- |
| Voltage | Density | Brightness | coordinates | coordinates | length |
| (V) | (mA/cm²) | (cd/m²) | (X axis) | (Y axis) | (nm) |
| 1 | 0 | 0 | 0 | 0 | 0 |
| 2 | 0 | 0 | 0 | 0 | 0 |
| 3 | 0 | 0 | 0 | 0 | 0 |
| 4 | 0.05 | 0 | 0 | 0 | 0 |
| 5 | 0.39 | 18.92 | 0.312 | 0.649 | 528 |
| 6 | 1.83 | 91.12 | 0.310 | 0.654 | 528 |
| 7 | 6.3 | 310 | 0.309 | 0.655 | 528 |
| 8 | 16.79 | 790.2 | 0.308 | 0.655 | 528 |

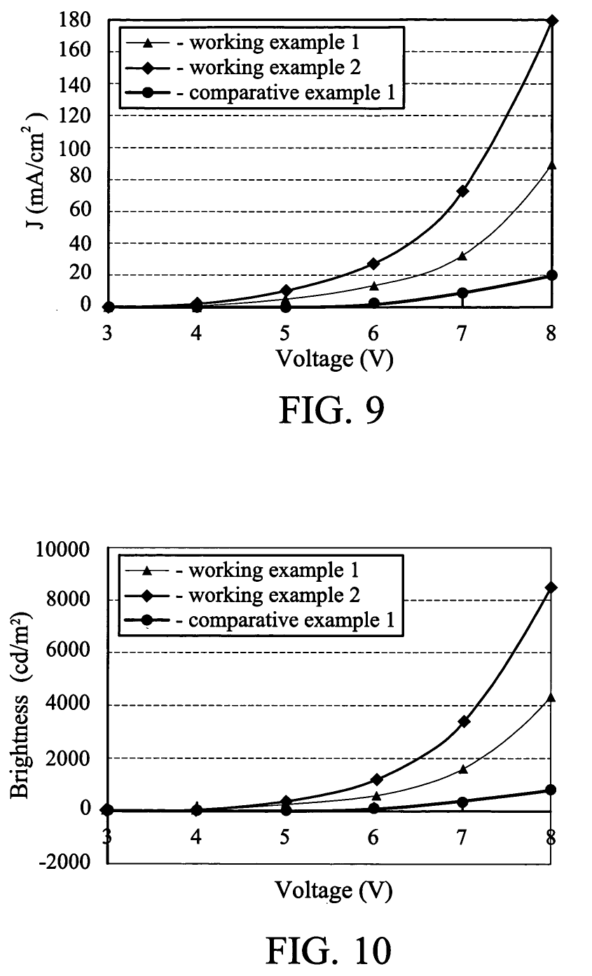

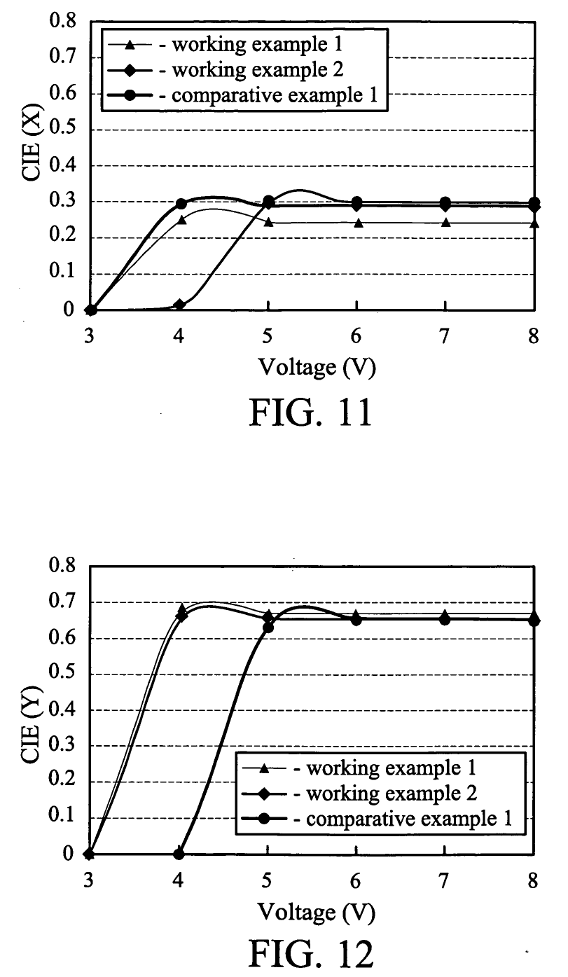

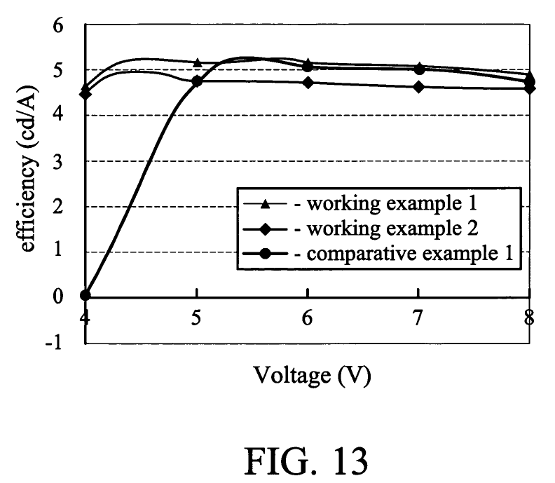

FIGS. 9˜13 also illustrate the differences between properties for the organic electroluminescent devices as described respectively in Working Example 1, Working Example 2, and Comparative Example 1. In FIGS. 9˜10 and Table 4, the organic electroluminescent devices disclosed in Working Examples 1 and 2 have lower operating voltages compared with the conventional organic electroluminescent device disclosed in Comparative Example 1. In Working Examples 1 and 2, the n-type semiconductor buffer layer not only prevents the underlying layers form damage by sputtering, but is also rigid enough to avoid deterioration or erosion causing ion bombardment. Further, as described in Working Example 2, since the composite transparent cathode electrode 180 exhibits sheet resistance less than 30 Ω/sq, the operating voltage thereof is reduced and efficiency increased.

TABLE 4
Under 2000nits

| | | | Power | CIE |
|---|---|---|---|---|
| | | efficiency | efficiency | chromaticity |
| | voltage(v) | (cd/A) | (lm/w) | coordinates |
| Examples 1 | 7.2 | 4.9 | 2.2 | (0.3, 0.65) |
| Examples 2 | 6.5 | 4.6 | 2.3 | (0.25, 0.67) |
| Comparative | 9.3 | 4.1 | 1.5 | (0.3, 0.65) |
| Examples 1 | | | | |

In conclusion, compared with conventional top-emission or dual emission organic electroluminescent devices, stability, luminescent efficiency, and operating voltage of the organic electroluminescent devices disclosed are all significantly improved.

Moreover, since composite transparent cathode electrodes with low sheet resistance are employed, high bias-voltage problems caused by conventional organic electroluminescent devices are solved thereby.

While the invention has been described by way of example and in terms of preferred embodiment, it is to be understood that the invention is not limited thereto. It is therefore intended that the following claims be interpreted as covering all such alteration and modifications as fall within the true spirit and scope of the invention.

What is claimed is:

1. An organic electroluminescent device, comprising:
a substrate;
a first electrode on the substrate;
an electroluminescent layer disposed on the first electrode;
a buffer layer disposed on the electroluminescent layer, comprising an n-type semiconductor material; and
a second electrode formed over the buffer layer.

2. The device as claimed in claim 1, wherein the second electrode is formed in contact with the buffer layer.

3. The device as claimed in claim 1, wherein the buffer layer has a thickness of 10˜2000 Å.

4. The device as claimed in claim 1, wherein the first electrode layer comprises a metal electrode or a transparent electrode.

5. The device as claimed in claim 1, wherein the substrate comprises a glass substrate, a plastic substrate, a ceramic substrate or a semiconductor substrate.

6. The device as claimed in claim 1, wherein the electroluminescent layer comprises a hole transport layer, emitting layer, electron transport layer, or combination thereof.

7. The device as claimed in claim 1, wherein the electroluminescent layer comprises small molecule or polymer material.

8. The device as claimed in claim 1, wherein the buffer layer comprises fullerene.

9. The device as claimed in claim 1, wherein the n-type semiconductor material has an energy gap exceeding 1.0 eV.

10. The device as claimed in claim 1, further comprising a conductive layer disposed between the electroluminescent layer and the buffer layer.

11. The device as claimed in claim 10, wherein the conductive layer has a thickness of 10˜500 Å.

12. The device as claimed in claim 1, wherein the second electrode comprises ITO, IZO, AZO, ZnO, GaN, GaInN, CdS, ZnS, CdSe, or ZnSe.

13. The device as claimed in claim 1, wherein the second electrode comprises:
a transparent electrode disposed on the buffer layer;
a metal layer disposed on the transparent layer; and
a protective layer disposed on the metal layer.

14. The device as claimed in claim 13, wherein the transparent electrode comprises ITO, IZO, AZO, ZnO, GaN, GaInN, CdS, ZnS, CdSe, or ZnSe.

15. The device as claimed in claim 13, wherein the protective layer comprises transparent conductive material, conductive polymer material, or semiconductor material with an energy gap exceeding 1.0 eV.

16. The device as claimed in claim 13, wherein the protective layer comprises ITO, IZO, AZO, ZnO, GaN, GaInN, CdS, ZnS, CdSe, or ZnSe.

17. The device as claimed in claim 13, wherein the protective layer comprises polypyrrole, polyaniline, or polythiophene.

18. The device as claimed in claim 13, wherein the metal layer has a thickness of 10˜500 Å.

19. The device as claimed in claim 13, wherein the metal layer has electric conductivity exceeding 10⁵ cm⁻¹Ω⁻¹.

20. The device as claimed in claim 13, wherein the metal layer comprises Ag.

21. The device as claimed in claim 13, wherein the second electrode has sheet resistance less than 30 Ω/sq.

22. A display device, comprising
an organic electroluminescent device as claimed in claim 1; and
a power source element, wherein the power source element electrically couples to the organic electroluminescent device.
